(19) United States
(12) Patent Application Publication
(10) Pub. No.: US 2011/0194261 A1
(43) Pub. Date: Aug. 11, 2011

(54) PREPREG, LAMINATE, PRINTED WIRING BOARD, AND SEMICONDUCTOR DEVICE

(76) Inventors: Nobuki TANAKA, Tokyo (JP); Michio Kimura, Tokyo (JP); Akihito Takahashi, Tokyo (JP)

(21) Appl. No.: 13/019,915

(22) Filed: Feb. 2, 2011

(30) Foreign Application Priority Data
Feb. 5, 2010 (JP) 2010-024113

(51) Int. Cl. H05K 1/18; H05K 1/05; C08J 5/08; B32B 27/04

(52) U.S. Cl. 361/748; 174/258; 442/60

(57) ABSTRACT

The present invention is to provide a prepreg capable of significantly decreasing generation of voids in a glass fiber base material and forming a printed wiring board and a semiconductor having high reliability, a laminate thereof, and a printed wiring board and a semiconductor device using the same. A prepreg comprising a glass fiber base material (A) impregnated with a thermosetting resin composition (B), wherein an inorganic particle having an average particle diameter of 500 nm or less is attached on a glass fiber surface of the glass fiber base material (A).

### TECHNICAL FIELD

The present invention relates to a prepreg, a laminate, a printed wiring board, and a semiconductor device.

### BACKGROUND

In recent years, with growing demand of higher function of electronics, high-density integration and high-density mounting of electronic components have been developed. Hence, printed wiring boards capable of high-density mounting and so on used for the electronic components have been developed in miniaturization and high density than ever before. As an insulating material of the printed wiring board, a laminate comprising prepregs laminated and cured by hot press has been widely used, each prepreg obtained by impregnating a glass fiber base material such as a glass woven fabric with a thermosetting resin such as an epoxy resin. However, with growing demand of higher density, the problem of decrease in insulation reliability has been exposed.

Also, in recent years, the density of components mounted on the printed wiring board has increased. Hence, among properties required for substrate materials of the printed wiring board, there have been requests on decrease in linear expansion characteristics, and increase in rigidity and heat resistance, particularly.

The coefficient of thermal expansion of a semiconductor element is 3 to 6 ppm/° C., which is lower than that of a general printed wiring board for a semiconductor plastic package. Therefore, when the semiconductor plastic package is subjected to thermal shock, warpage of the semiconductor plastic package is caused due to the difference of the coefficient of thermal expansion between the semiconductor element and the printed wiring board for the semiconductor plastic package. This warpage may cause connection failure between the semiconductor element and the printed wiring board of the semiconductor plastic package, or between the semiconductor plastic package and the printed wiring board being mounted. In order to decrease the warpage to ensure the connection reliability, it is necessary to develop a laminate having low coefficient of thermal expansion. In addition, it is also required that a part of or the whole printed wiring board has high rigidity so that the printed wiring board can connect with components or other substrates, and components can be mounted on the printed wiring board. In addition, heat resistance has been required for the prepreg from the viewpoint of the reliability of electrical and electronic components.

To decrease linear expansion characteristics, and increase rigidity and heat resistance, there have been attempts to increase the density of the glass woven fabric (for example, Patent Literature 1) and to increase the amount of fillers in the resin composition (for example, Patent Literature 2).

However, if the density of the glass woven fabric increases, the area of the part called as a basket hole surrounded by warp and weft, where there is no glass-fiber yarn, decreases. Hence, impregnation of resins and fillers into the glass woven fabric deteriorates, and voids (spaces) that are not impregnated with the resins and the fillers generate in the glass woven fabric. Thereby, a problem of decrease in insulation reliability of the prepreg and a problem of not being able to form the prepreg have been caused. Particularly, since impregnation of the fillers into the glass woven fabric having high density deteriorates, it has not been able to impregnate the glass woven fabric having high density with the resin composition containing a large amount of fillers without generating voids. Therefore, the achievement of low linear expansion characteristics, high rigidity and high heat resistance has been still insufficient in the substrate material of the printed wiring board, and the achievement of reliability in the semiconductor device has been also insufficient. As attempts to increase impregnation of the resin composition into the glass woven fabric, there have been subjecting the glass woven fabric to surface treatment using a silane coupling agent, and performing physical processing (Patent Literature 3). However, such surface treatment and physical processing have been insufficient to sufficiently impregnate the glass woven fabric with the fillers so as to decrease the generation rate of voids (spaces).

### Citation List

### [Patent Literature]

[Patent Literature 1] Japanese Patent Application Laid-Open (JP-A) No. 2002-192521
[Patent Literature 2] JP-A No. 2007-224269
[Patent Literature 3] JP-A No. 2009-173765

### SUMMARY OF INVENTION

### Technical Problem

An object of the present invention is to provide a prepreg capable of significantly decreasing generation of voids in a glass fiber base material and forming a printed wiring board and a semiconductor having high reliability, a laminate thereof, and a printed wiring board and a semiconductor device using the same.

### Solution to Problem

The above object can be attained by the following [1] to [12].

[1] A prepreg comprising a glass fiber base material (A) impregnated with a thermosetting resin composition (B), wherein an inorganic particle having an average particle diameter of 500 nm or less is attached on a glass fiber surface of the glass fiber base material (A).

[2] The prepreg according to the above [1], wherein the inorganic particle of the glass fiber base material (A) is a silica particle.

[3] The prepreg according to the above [1] or [2], wherein a thickness of the glass fiber base material (A) is 150 μm or less.

[4] The prepreg according to any of the above [1] to [3], wherein the glass fiber surface of the glass fiber base material (A) is processed by a treatment liquid in which the inorganic particles are dispersed.

[5] The prepreg according to any of the above [1] to [4], wherein the thermosetting resin composition (B) contains an inorganic filler.

[6] The prepreg according to any of the above [1] to [5], wherein the thermosetting resin composition (B) contains an epoxy resin.

[7] The prepreg according to any of the above [1] to [6], wherein the thermosetting resin composition (B) contains a cyanate resin.

[8] The prepreg according to any of the above [1] to [7], wherein the inorganic filler contained in the thermosetting resin composition (B) has an average particle diameter of from 0.1 μm to 5.0 μm.

[9] A laminate comprising the prepregs defined by any of the above [1] to [8] being cured.

[10] The laminate according to the above [9] comprising a conducting layer disposed on at least one outer surface of the prepreg.

[11] A printed wiring board comprising the laminate defined by the above [9] or [10] subjected to wiring processing.

[12] A semiconductor device comprising the printed wiring board defined by the above [11], and a semiconductor element mounted on the printed wiring board.

### Advantageous Effects of Invention

According to the present invention, there is an advantage that even if the glass fiber base material has high density, generation of voids in the glass fiber base material significantly decreases and a highly reliable printed wiring board and semiconductor device can be produced since the prepreg of the present invention comprises the glass fiber base material (A) impregnated with the thermosetting resin composition (B), wherein an inorganic particle having an average particle diameter of 500 nm or less is attached on a glass fiber surface of the glass fiber base material (A).

In addition, according to the present invention, it is possible to achieve increase in density of the glass fiber base material and amount of the fillers in the thermosetting resin composition, and to obtain a laminate capable of achieving low linear expansion characteristics, high rigidity, and high heat resistance. Thereby, the reliability of the semiconductor device increases.

### BRIEF DESCRIPTION OF DRAWINGS

FIG. 1 is a SEM photograph of a surface of a glass fiber base material, in which inorganic particles having an average particle diameter of 100 nm are attached, used in Example 4.

FIG. 2 is a SEM photograph of a surface of a glass fiber base material, in which inorganic particles are not attached, used in Comparative example 4.

FIG. 3 is a SEM photograph of cross-sectional observation of a copper-clad laminate in Example 4.

FIG. 4 is a SEM photograph of cross-sectional observation of a copper-clad laminate in Comparative example 4.

### DESCRIPTION OF EMBODIMENTS

Hereinafter, a prepreg, a laminate, a printed wiring board and a semiconductor device of the present invention will be described in detail.

The prepreg of the present invention comprises a glass fiber base material (A) impregnated with a thermosetting resin composition (B), wherein an inorganic particle having an average particle diameter of 500 nm or less is attached on a glass fiber surface of the glass fiber base material (A).

“Attached” used herein means that even if the glass fiber base material (A) is immersed in an organic solvent, the inorganic particles are immobilized on the glass fiber surface to the extent that the inorganic particles do not peel off. “Attached” includes the case that the inorganic particles are attached on the glass fiber surface via coupling agents or resins. The inorganic particles are immobilized on the glass fiber surface to the extent that the inorganic particles do not peel off even if the glass fiber base material (A) is immersed in an organic solvent used for the thermosetting resin composition (B) to be impregnated into the glass fiber base material (A).

In the prepreg of the present invention, since the inorganic particles having an average particle diameter of 500 nm or less are attached on the glass fiber surface of the glass fiber base material (A), the thermosetting resin composition easily impregnates into the glass fiber base material even if the glass fiber base material has high density, and thereby, generation of voids in the glass fiber base material significantly decreases. The reason thereof is presumed that since the inorganic particles having an average particle diameter of 500 nm or less are attached on the surface of the glass fiber having a fiber diameter generally of μm order, moderate spaces are provided between glass fibers, thus, the impregnation of not only resins but also fillers in the thermosetting resin composition increases. According to the present invention, since generation of voids in the glass fiber base material is significantly decreased, the printed wiring board and semiconductor device having high reliability are produced.

According to the present invention, even if the glass fiber base material has high density and the amount of the filler in the thermosetting resin composition increases, it is possible to decrease generation of voids in the glass fiber base material. Thereby, it is possible to obtain a laminate capable of achieving low linear expansion characteristics, high rigidity, and high heat resistance, and therefore, the reliability of the semiconductor device using the laminate increases.

Examples of the glass fiber base material (A) used in the present invention include glass woven fabric and glass nonwoven fabric. Thereby, the strength of the prepreg increases, and the water absorption of the prepreg decreases. In addition, the linear expansion coefficient of the prepreg decreases.

Examples of glass materials of the glass fiber include E glass, D glass, Q glass, S glass, NE glass, and T glass. Among the above, when T glass is used, the glass fiber base material can achieve high elasticity, and a prepreg having low thermal expansion coefficient can be realized. In addition, if the thermosetting resin composition (B) that will be hereinafter described contains a cyanate resin, the affinity of T glass with the thermosetting resin composition (B) is particularly excellent, and more excellent low expansion characteristics and high elastic modulus (high rigidity) can be achieved. The composition of T glass as used herein is SiO₂ of 64 to 66% by weight, Al₂O₃ of 24 to 26% by weight, and MgO of 9 to 11% by weight.

As the glass fiber, glass fiber made of glass filaments having an average fiber diameter in the range of 2.5 to 9.0 μm is preferable.

An example of the glass woven fabric includes fabric using a glass fiber bundle in the range of 5 to 500 TEX (preferably from 22 to 68 TEX) as a warp and a weft. The weaving density of the glass woven fabric is preferably in the range from 10 to 200 threads/25 mm, more preferably from 15 to 100 threads/25 mm, still more preferably from 15 to 80 threads/25 mm for both warp and weft. A woven structure is preferably a plain-woven structure. The glass woven fabric may also have a woven structure such as basket weave, sateen weave or twill weave.

The mass of the glass fiber base material is preferably in the range from 5 to 400 g/m², more preferably from 10 to 300 g/m².

The thickness of the glass fiber base material (A) used in the present invention is preferably 150 μm or less from the viewpoint of impregnation.

As the inorganic particle having an average particle diameter of 500 nm or less attached on the glass fiber surface, for example, a particle of silica, alumina or zirconium oxide is used. Among the above, the silica particle is preferable from the viewpoint of low expansion characteristics. As the silica particle, for example, dry fused silica produced by the combustion method, or wet sol-gel silica produced by the precipitation method or the gel method is used. Among the above, colloidal silica is preferably used since the colloidal silica uniformly attaches on the glass fiber surface.

The average particle diameter of the inorganic particles attached on the glass fiber surface is 500 nm or less, preferably from 10 to 300 nm, more preferably from 40 to 150 nm, from the viewpoint of impregnation. If the average particle diameter is less than 10 nm, the effect of increasing the distance between filaments is small, thus, the impregnation may not improve. If the average particle diameter is more than 500 nm, it is difficult for the inorganic particles to enter into the spaces between filaments, thereby, the workability may decrease.

The average particle diameter in the present invention is defined by D50, and is measured by the laser diffraction and scattering method. Specifically, the inorganic particles are dispersed in water by ultrasonic wave, and then, the particle size distribution of the inorganic particles is measured based on volume by means of a laser diffraction particle size analyzer (product name: LA-500; manufactured by HORIBA). The median diameter is referred to as the average particle diameter.

The surface of the glass fiber base material may be subjected to surface treatment by a surface treatment agent such as a silane coupling agent, or a titanate coupling agent. It is preferable to appropriately select the surface treatment agent considering the reactivity of the surface treatment with the thermosetting resin to be impregnated. The examples include silane coupling agents having an unsaturated double bond such as vinyltriethoxysilane, vinyltrimethoxysilane, and γ-(methacryloyloxypropyl)trimethoxysilane; silane coupling agents having an epoxy group such as β-(3,4-epoxycyclohexyl)ethyltrimethoxysilane, γ-glycidyloxypropyl trimethoxysilane, and γ-glycidyloxypropyl methyldiethoxysilane; silane coupling agents having a mercapto group such as γ-mercaptopropyl trimethoxysilane; and silane coupling agents having an amino group such as γ-aminopropyl triethoxysilane, N-β-(aminoethyl)y-aminopropyl trimethoxysilane, and N-β-(N-vinylbenzylaminoethyl)-γ-aminopropyl trimethoxysilane.

In addition, the surface of the glass fiber base material maybe subjected to surface treatment by aqueous polyurethane, etc. from the viewpoint of improving rigidity. An example of the aqueous polyurethane includes a compound obtained by the reaction of polyisocyanate having two or more isocyanate groups such as 4,4′-diphenylmethane diisocyanate, 2,4- or 2,6-tolylene diisocyanate, hexamethylene diisocyanate or isophorone diisocyanate with water-soluble polyoxyalkylene polyol.

A method for obtaining the glass fiber base material in which the inorganic particles having an average particle diameter of 500 nm or less are attached on the glass fiber surface is not particularly limited, and the example includes a method of performing treatment such as applying a treatment liquid, in which at least inorganic particles having an average particle diameter of 500 nm or less are dispersed in a solvent such as water or an organic solvent, on the glass fiber surface. As the treatment liquid in which the inorganic particles are dispersed, a colloidal silica-containing solution is preferably used. The surface treatment agent and the resin as described above may be mixed with the treatment liquid.

Examples of the method for applying the treatment liquid on the glass fiber surface include: a method of dipping the glass fiber base material in the treatment liquid; a method of applying the treatment liquid by means of a coater selected from various kinds; and a method of spraying the treatment liquid by means of a spray. Among the above, the method of dipping the glass fiber base material in the treatment liquid is preferable. Thereby, impregnation of the treatment liquid into the glass fiber base material improves. It is also preferable to subject the glass fiber base material to ultrasonic vibration upon dipping the glass fiber material in the treatment liquid. As a method for drying a solvent after applying the treatment liquid on the glass fiber base material, a known method such as hot air or electromagnetic wave is applicable. After drying the solvent, the surface treatment agent and the resin as described above may be further applied on the glass fiber base material.

The surface treatment on the glass fiber base material may be performed by a known surface treatment method using the above surface treatment agent at the stage that a binder required for weaving is removed. In addition, opening fiber processing may be performed on the glass fiber base material by high pressure stream such as a columnar stream, or ultrasonic wave by a high-frequency vibration method in water.

In the glass fiber base material (A), the amount of the inorganic particles having an average particle diameter of 500 nm or less attached on the glass fiber surface is preferably from 1.0×10⁻³ to 5.0×10⁻² parts by weight, more preferably from 1.0×10⁻² to 4.0×10⁻² parts by weight, with respect to 100 parts by weight of the glass fiber base material (A) from the viewpoint of decreasing generation of voids in the glass fiber base material, and the formability of the prepreg.

Next, the thermosetting resin composition (B) used in the present invention will be described.

The thermosetting resin composition (B) contains at least a thermosetting resin. Examples of the thermosetting resin include epoxy resins, phenol resins, urea resins, melamine resins, silicon resins, polyester resins and cyanate resins. Among the above, the epoxy resins and/or cyanate resins are preferable. This is because the linear expansion of the prepreg decreases, and the heat resistance of the prepreg significantly improves if the epoxy resin and/or cyanate resin is used. In addition, there is an advantage of excellent heat resistance, impact resistance and rigidity, if the epoxy resin and/or cyanate resin is used in combination with a filler charged in high content. Since the epoxy resin and/or cyanate resin having high heat resistance and low linear expansion coefficient has high viscosity, it is difficult for the epoxy resin and/or cyanate resin to be impregnated into the glass fiber base material. However, by using the above glass fiber base material (A) of the present invention, it is possible to preferably impregnate such a resin having high viscosity. According to the present invention, by achieving the combination of the glass fiber base material (A), the epoxy resin and/or cyanate resin having high heat resistance and low linear expansion coefficient, and the filler charged in high content, it is possible to obtain a prepreg having low-linear expansion coefficient, excellent heat resistance, impact resistance, and rigidity.

Specific examples of the epoxy resin include bisphenol A type epoxy resins, bisphenol F type epoxy resins, phenol novolac type epoxy resins, cresol novolac type epoxy resins, bisphenol A novolac type epoxy resins, biphenyl novolac type epoxy resins, anthracene type epoxy resins, dihydroanthracene type epoxy resins, trifunctional phenol type epoxy resins, tetrafunctional phenol type epoxy resins, naphthalene type epoxy resins, biphenyl type epoxy resins, aralkyl-modified epoxy resins, alicyclic epoxy resins, polyol type epoxy resins, glycidylamine and glycidyl ester, compounds produced by epoxidizing a double bond such as butadiene, and compounds obtained by the reaction of a hydroxyl group-containing silicone resin with epichlorohydrin.

In the present invention, the aralkyl-modified epoxy resins are preferably used from the viewpoint of flame resistance, low-water absorption and solder heat resistance. As the aralkyl-modified epoxy resins, for example, the epoxy resins represented by the following formula (1) can be exemplified. Specific examples include phenol aralkyl epoxy resins, biphenyl aralkyl epoxy resins, and naphthalene aralkyl epoxy resins.

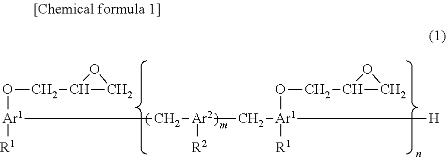

wherein each of Ar¹ and Ar² is independently an aryl group having a substituent of monocyclic or polycyclic aromatic hydrocarbon such as a phenyl group, a naphthyl group or a biphenyl group; each of R¹ and R² is independently a hydrogen atom, alkyl group or aryl group; m is an integer from 1 to 5; and n is an integer from 1 to 50.

Among the above, the biphenyl aralkyl epoxy resins and/or phenol aralkyl epoxy resins are preferably used from the viewpoint of flame resistance. The content of the aralkyl-modified epoxy resin is not particularly limited, and is preferably from 5 to 50% by weight, more preferably from 20 to 50% by weight, in the total solid content of the resin composition (B) from the viewpoint of low-water absorption and solder heat resistance. Among the above aralkyl-modified epoxy resins, the biphenyl aralkyl epoxy resins are particularly preferable from the viewpoint of having high epoxy equivalent and obtaining high effect of low-water absorption. In addition, if the biphenyl aralkyl epoxy resin and/or phenol aralkyl epoxy resin is used in the present invention, the number of the repeating unit thereof is preferably from 2 to 7, from the viewpoint of solder heat resistance at 260° C. If the number of the repeating unit is more than 7, the compatibility of the epoxy resin with the cyanate resin may deteriorate in the case of using the epoxy resin and the cyanate resin in combination.

The “solid content” as used in the present invention includes all components excluding a solvent, and also includes liquid resin components, etc.

The cyanate resin used in the present invention can be obtained by the reaction of, for example, a cyanogen halide compound with phenol. Specific examples of the cyanate resin include novolac type cyanate resins such as phenol novolac type cyanate resins and cresol novolac type cyanate resins; and bisphenol type cyanate resins such as bisphenol A type cyanate resins, bisphenol AD type cyanate resins, and tetramethyl bisphenol F type cyanate resins.

Among the above, it is particularly preferable to contain the novolac type cyanate resin. In particular, 10% by weight or more of the novolac type cyanate resin is preferably contained in the total solid content of the resin composition (B). Thereby, the heat resistance (glass transition temperature and thermal decomposing temperature) of the prepreg can be improved. Further, the thermal expansion coefficient of the prepreg (particularly, the thermal expansion coefficient in the thickness direction of the prepreg) can decrease. If the thermal expansion coefficient in the thickness direction of the prepreg decreases, the stress-strain of a multilayer printed wiring board can decrease. Furthermore, in the multilayer printed wiring board having a fine interlayer connection, the connection reliability thereof significantly can be improved.

Among the novolac type cyanate resins, the novolac type cyanate resin represented by the following formula (I) is preferable. It is preferable to use the novolac type cyanate resin represented by the formula (I) having a weight average molecular weight of 2,000 or more, more preferably from 2,000 to 10,000, still more preferably from 2,200 to 3,500, in combination with the novolac type cyanate resin represented by the formula (I) having a weight average molecular weight of 1,500 or less, more preferably from 200 to 1,300. The weight average molecular weight in the present invention is a value measured by a polystyrene calibrated-gel permeation chromatography.

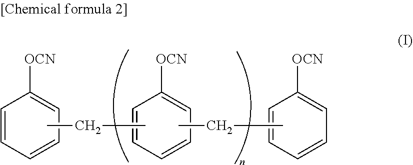

As the cyanate resin, the cyanate resin represented by the following formula (II) is also preferably used. The cyanate resin represented by the following formula (II) is obtained by condensing a naphthol aralkyl resin obtained by the reaction of naphthol such as α-naphthol or β-naphthol and p-xylylene glycol, α,α′-dimethoxy-p-xylene, or 1,4-di(2-hydroxy-2-propyl)benzene,with a cyanic acid. “n” in the formula (II) is more preferably 10 or less. If “n” is 10 or less, there is a tendency that the resin viscosity does not become high and impregnation into the base material is good, thus the performance of a laminate is not decreased. In addition, there is a tendency that the polymerization in the molecule upon synthesis is hardly caused and the liquid separability upon water washing improves, thus the decrease in yield is prevented.

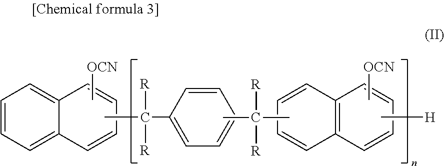

wherein R is a hydrogen atom or a methyl group; and “n” is an integer of 1 or more.

A curing agent may be used in combination with the thermosetting resin composition. For example, if the thermosetting resin is the epoxy resin or the cyanate resin, a phenol resin or a curing accelerator of epoxy resin or cyanate resin can be used. The phenol resin is not particularly limited, and the examples include novolac type phenol resins such as phenol novolac resins, cresol novolac resins, bisphenol A novolac resins, and arylalkylene type novolac resins; and resol type phenol resins such as unmodified resol phenol resins and oil-modified resol phenol resins modified by wood oil, linseed oil, or walnut oil. As the phenol resin, the phenol novolac or cresol novolac resin is preferable. Among the above, the biphenyl aralkyl modified phenol novolac resins are preferable from the viewpoint of hygroscopic solder heat resistance.

They may be used alone or in combination of two or more kinds having different weight average molecular weight. One or more kinds of polymers and prepolymers thereof may also be used in combination.

The curing accelerator is not particularly limited. The examples include organometallic salts such as zinc naphthenate, cobalt naphthenate, tin octylate, cobalt octylate, bis(acetylacetonato)cobalt (II), and tris(acetylacetonato)cobalt (III); tertiary amines such as triethylamine, tributylamine, and diazabicyclo[2,2,2]octane; imidazoles such as 2-methylimidazole, 2-phenylimidazole, 2-phenyl-4-methylimidazole, 2-ethyl-4-ethylimidazole, 1-benzyl-2-methyl imidazole, 1-benzyl-2-phenylimidazole, 2-undecylimidazole, 1-cyanoethyl-2-ethyl-4-methylimidazole, 1-cyanoethyl-2-undecylimidazole, 2-phenyl-4-methyl-5-hydroxyimidazole, 2-phenyl-4,5-dihydroxyimidazole, and 2,3-dihydro-1H-pyrrolo(1,2-a)benzimidazole; phenol compounds such as phenol, bisphenol A, and nonylphenol; organic acids such as acetic acid, benzoic acid, salicylic acid and p-toluenesulfonic acid; onium salt compounds; and the mixtures thereof. They may be used alone including the derivatives thereof or in combination of two or more kinds including the derivatives thereof. Among the above curing accelerators, the onium salt compounds are preferable from the viewpoint of being excellent in storage stability of varnish, and thus improving the yield upon production of the prepreg.

The onium salt compound is not particularly limited. For example, the onium salt compound represented by the following formula (2) can be used.

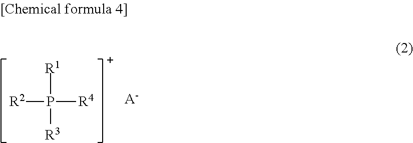

wherein P is a phosphorus atom; each of R¹, R², R³ and R⁴ is an organic group having a substituted or unsubstituted aromatic ring or heterocyclic ring, or a substituted or unsubstituted aliphatic group, and may be the same or different from each other; A⁻ is an anion of n(n≧1)-valent proton donor having at least one or more protons in a molecule which can be released out from the molecule, or a complex anion thereof.

The compound represented by the formula (2) is synthesized by the method disclosed, for example, in JP-A No. 2004-231765. An example of the method comprises the steps of: charging 4,4′-bisphenol S, tetraphenylphosphonium bromide and ion-exchange water; dropping an aqueous solution of sodium hydroxide while agitating and heating; and purifying precipitated crystal by filtrating, water washing and vacuum drying. Thus, the compound is obtained.

In addition, the onium salt compound is preferably a compound represented by the following formula (3).

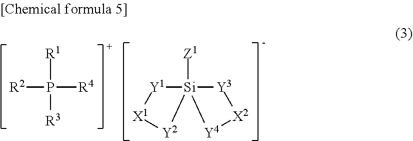

wherein P is a phosphorus atom; each of R¹, R², R³ and R⁴ is an organic group having a substituted or unsubstituted aromatic ring or heterocyclic ring, or a substituted or unsubstituted aliphatic group, and may be the same or different from each other; X¹ is an organic group bonding to substituents Y¹ and Y²; X² is an organic group bonding to substituents Y³ and Y⁴; each of Y¹ and Y² is a group obtained by releasing protons from a proton donating substituent; Y¹ and Y² in the same molecule bond with a silicon atom to form a chelate structure; each of Y³ and Y⁴ is a group obtained by releasing protons from a proton donating substituent; Y³ and Y⁴ in the same molecule bond with a silicon atom to form a chelate structure; X¹ and X² may be the same or different from each other; Y¹, Y², Y³, and Y⁴ may be the same or different from each other; and Z¹ is an organic group having a substituted or unsubstituted aromatic ring or heterocyclic ring, or a substituted or unsubstituted aliphatic group.

The compound represented by the formula (3) is synthesized by the method disclosed, for example, in JP-A No. 2007-246671. An example of the method comprises the steps of: uniformly dissolving 2,3-dihydroxynaphthalene, 3-mercaptopropyltrimethoxysilane and methanol while agitating; dropping an acetonitrile solution of triethylamine in a flask while agitating; further dropping a methanol solution of tetraphenylphosphonium bromide gradually; and purifying precipitated crystal by filtration, water washing, and vacuum drying. Thus, the compound is obtained.

Also, the onium salt compound represented by the following formula (4) is preferable.

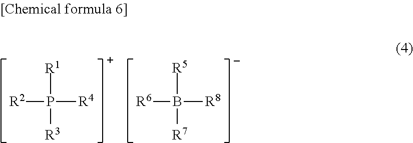

wherein P is a phosphorus atom; B is a boron atom; each of R¹, R², R³ and R⁴ is an organic group having a substituted or unsubstituted aromatic ring or heterocyclic ring, or a substituted or unsubstituted aliphatic group, and may be the same or different from each other; each of R⁵, R⁶, R⁷ and R⁸ is an organic group having a substituted or unsubstituted aromatic ring or heterocyclic ring, or a substituted or unsubstituted aliphatic group, or a n(n≧1)-valent proton donor having at least one or more protons in a molecule which can be released out from the molecule; and may be the same or different from each other.

The compound represented by the formula (4) is synthesized by the method disclosed, for example, in JP-A No. 2000-246113. An example of the method comprises the steps of: uniformly dissolving boric acid, 3-hydroxy-2-naphthoic acid, methyl cellosolve and pure water while agitating; dropping a solution in which tetraphenylphosphonium bromide is uniformly dissolved in a methanol/pure water mixed solvent in a flask while agitating; and purifying precipitated crystal by filtration, water washing, and vacuum drying. Thus, the compound is obtained.

The content of the onium salt compound is not particularly limited, and is preferably from 0.01 to 10% by weight, more preferably from 0.1 to 5% by weight, still more preferably from 0.2 to 2.5% by weight, with respect to the total solid content of the thermosetting resin composition (B) containing the epoxy resin and/or cyanate resin. Thereby, excellent curability, flowability and cured product properties can be exhibited.

The thermosetting resin composition may contain a maleimide compound from the viewpoint of heat resistance. The maleimide compound is not particularly limited if it has one or more maleimide groups in a molecule. The specific examples include N-phenylmaleimide, N-hydroxyphenylmaleimide, bis(4-maleimidephenyl)methane, 2,2-bis{4-(4-maleimidephenoxy)-phenyl}propane, bis(3,5-dimethyl-4-maleimidephenyl)methane, bis(3-ethyl-5-methyl-4-maleimidephenyl)methane, bis(3,5-diethyl-4-maleimidephenyl)methane, polyphenylmethanemaleimide, prepolymers of the above maleimide compounds, and prepolymers of the maleimide compound and an amine compound.

In addition, the thermosetting resin composition may contain polyamide-imide from the viewpoint of the adhesion to a metal foil.

The amount of the thermosetting resin in the thermosetting resin composition (B) is not particularly limited, and may be appropriately adjusted according to its purpose. The thermosetting resin is preferably from 10 to 90% by weight, more preferably from 20 to 70% by weight, still more preferably from 25 to 50% by weight, in the total solid content of the composition (B).

If the epoxy resin and/or cyanate resin is used as the thermosetting resin, the epoxy resin is preferably from 5 to 50% by weight, more preferably from 5 to 25% by weight, in the total solid content of the resin composition (B). The cyanate resin is preferably from 5 to 50% by weight, more preferably from 10 to 25% by weight, in the total solid content of the resin composition (B).

It is preferable that the thermosetting resin composition (B) contains an inorganic filler from the viewpoint of low-thermal expansion and mechanical strength. The inorganic filler is not particularly limited, and the examples include: silicate salts such as talc, calcined clay, uncalcined clay, mica and glass; oxides such as titanic oxide, alumina, silica and fused silica; carbonates such as calcium carbonate, magnesium carbonate, and hydrotalcite; metallic hydroxides such as aluminum hydroxide, boehmite (AlO(OH), and boehmite which is generally called as “pseudo” boehmite (that is, Al₂O₃.xH₂O, herein, x is from 1 to 2)), magnesium hydroxide and calcium hydroxide; sulfate salts and sulfites such as barium sulfate, calcium sulfate and calcium sulfite; borate salts such as zinc borate, barium metaborate, aluminum borate, calcium borate and sodium borate; nitrides such as aluminum nitride, boron nitride, silicon nitride and carbon nitride; and titanates such as strontium titanate and barium titanate. They may be used alone, or in combination of two or more kinds.

Among the above, magnesium hydroxide, aluminum hydroxide, boehmite, silica, fused silica, talc, calcined talc and alumina are preferable. The silica is more preferable from the viewpoint of low-thermal expansion characteristics and insulation reliability. The spherical fused silica is even more preferable. In addition, the aluminum hydroxide is preferable from the viewpoint of flame resistance. In the present invention, since the glass fiber base material (A), which is easily impregnated even with an inorganic filler, is used, it is able to increase the amount of the inorganic filler in the thermosetting resin composition (B). If the inorganic filler in the thermosetting resin composition (B) is contained in high concentration, drill durability upon through hole processing by means of the drill may deteriorate. However, it is preferable that boehmite is contained as the inorganic filler since the drill durability becomes excellent.

The particle diameter of the inorganic filler is not particularly limited. It is possible to use a monodisperse inorganic filler, and a polydisperse inorganic filler. Further, one or more kinds of the monodisperse and/or polydisperse inorganic filler can be used in combination. The average particle diameter of the inorganic filler is not particularly limited, and is preferably from 0.1 μm to 5.0 μm, more preferably from 0.1 μm to 3.0 μm. If the particle diameter of the inorganic filler is less than the above lower limit, the viscosity of the resin composition may increase, thus, the workability upon producing the prepreg may be affected. If the particle diameter of the inorganic filler exceeds the above upper limit, phenomenon such as sedimentation of the inorganic filler in the resin composition may be caused. The average particle diameter is measured by means of a laser diffraction particle size analyzer (a general machine such as SALD-7000 (product name) manufactured by SHIMADZU CORPORATION).

The content of the inorganic filler is not particularly limited, and is preferably from 10% by weight to 90% by weight, more preferably from 30% by weight to 80% by weight, still more preferably from 50% by weight to 75% by weight, in the total solid content of the resin composition (B). If the cyanate resin and/or a prepolymer thereof is contained in the resin composition, the content of the inorganic filler is preferably from 50 to 75% by weight in the total solid content of the resin composition. If the content of the inorganic filler exceeds the above upper limit, the flowability of the resin composition may significantly decrease, which is not preferable. If the content of the inorganic filler is less than the above lower limit, the strength of the insulating layer made of the resin composition may not be sufficient, which is not preferable.

The thermosetting resin composition (B) may further contain a coupling agent. The coupling agent may be contained for improvement in wettability of the interface between the thermosetting resin and the inorganic filler to uniformly fix the resins and the inorganic filler on the base material, resulting in improvement of the heat resistance, particularly the solder heat resistance after moisture absorption.

The coupling agent is not particularly limited and the examples include epoxy silane coupling agents, cationic silane coupling agents, amino silane coupling agents, titanate coupling agents, and silicone oil type coupling agents. Thereby, the wettability of the interface between the thermosetting resin and the inorganic filler increases, thus, the heat resistance of the prepreg is further improved.

The content of the coupling agent is not particularly limited, and is preferably from 0.05 to 3 parts by weight, more preferably from 0.1 to 2 parts by weight, with respect to 100 parts by weight of the inorganic filler. If the content is less than the above lower limit, the inorganic filler may not be sufficiently covered, thus, the effect of improving heat resistance may decrease. If the content exceeds the above upper limit, the reaction may be affected and the transverse strength, etc. may decrease.

The thermosetting resin composition (B) may contain additives, if necessary, besides the above components. Examples of the additives include defoaming agents, leveling agents, ultraviolet absorbing agents, foaming agents, antioxidants, flame retardants, flame-retardant aids such as silicone powders, and ion scavengers.

The thermosetting resin composition (B) preferably contains at least the epoxy resin, the cyanate resin, and the inorganic filler from the viewpoint of easily achieving low linear expansion characteristics, high rigidity, and high heat resistance of the prepreg. In particular, the solid content of the resin composition (B) preferably contains the epoxy resin from 5 to 50% by weight, the cyanate resin from 5 to 50% by weight, and the inorganic filler from 10 to 90% by weight, and more preferably contains the epoxy resin from 5 to 25% by weight, the cyanate resin from 10 to 25% by weight, and the inorganic filler from 30 to 80% by weight. Particularly, it is preferable to use the aralkyl-modified epoxy resin as the epoxy resin and the novolac type cyanate resin as the cyanate resin in combination.

For the method of impregnating the glass fiber base material (A) with the thermosetting resin composition (B) obtained in the present invention, a general device for impregnating coating can be used. Upon impregnating the glass fiber base material (A) with the thermosetting resin composition (B) in the present invention, a varnish having the resin composition (B) dissolved in a solvent is generally used, which is preferable from the viewpoint of impregnation. It is preferable that the solvent to be used has good solubility to the composition, however, a poor solvent may be used to the extent that it does not have adverse effect. Examples of the solvent having good solubility include methyl ethyl ketone and cyclohexanone. The varnish obtained by dissolving the resin composition of the present invention in the solvent is impregnated into the base material followed by drying at 80 to 200° C., thereby, the prepreg is obtained.

The prepreg is able to be used after curing the resin constituting the prepreg by heating, or be used even if the resin is in the uncured state. Further, the prepreg is able to be used if the resin is in a desired semi-cured state between cured and uncured state. Specifically, it is possible to laminate a metal foil on the prepreg, the resin of which is in the uncured state, and form a circuit.

The reaction rate of the resin composition of the uncured and semi-cured prepreg is not particularly limited, and is preferably 30% or less, more preferably from 0.1 to 20%, from the viewpoint of flexibility and prevention of powder generation. The reaction rate is obtained by differential scanning calorimetry (DSC). That is, the reaction rate is calculated by the following formula (I), which compares the area of exothermic peak caused by the reaction in DSC of the uncured resin composition and that of the resin composition in the prepreg. The measurement is conducted at the heating rate of 10° C./minute under nitrogen atmosphere.

Reaction rate (%)=(1-reaction peak area of resin composition in prepreg/reaction peak area of unreacted resin composition)×100 Formula (I)

The exothermic peak of the unreacted resin composition is measured using a sample obtained by impregnating a varnish made of the resin composition to be used into the base material, drying thus obtained base material by air at 40° C. for 10 minutes, and removing the solvent at 40° C. under 1 kPa and vacuum for 1 hour.

Next, the laminate will be described.

The laminate of the present invention comprises the prepregs of the present invention being cured. It is preferable that the laminate of the present invention comprises a conducting layer disposed on at least one outer surface of the prepreg of the present invention.

A metal foil may be used as the conducting layer or the conducting layer may be formed by plating. Examples of the metal foil include metal foils made of copper, copper alloy, aluminum, aluminum alloy, silver, silver alloy, gold, gold alloy, zinc, zinc alloy, nickel, nickel alloy, tin, tin alloy, iron, and iron alloy. In addition, the conducting layer made of copper, copper alloy, etc. as described above may be formed by plating.

The laminate of the present invention is obtained, for example, by layering the metal foil on both surfaces of the laminate, in which at least one or more prepregs are laminated, followed by hot press. The heating temperature is not particularly limited, and is preferably from 120 to 230° C., more preferably from 150 to 210° C. The pressure to be applied is not particularly limited, and is preferably from 0.5 to 5 MPa, more preferably from 1 to 3 MPa.

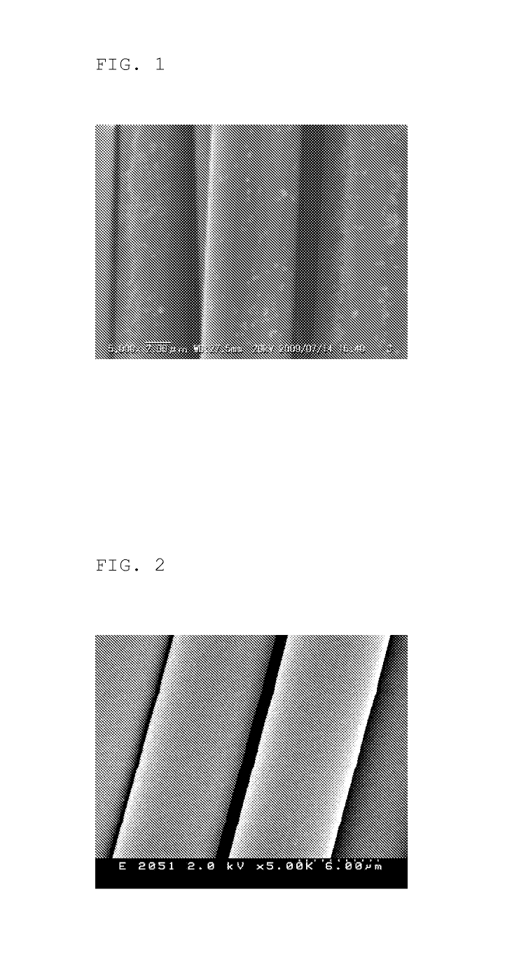

As another method for producing the metal-clad laminate of the present invention, a method using a long base material and a long metal foil as disclosed in JP-A No. H8-150683 is applicable (paragraphs 0005 and 0006, and FIG. 1 of JP-A No. H8-150683). In this case, the laminate is produced right after or at the same time as producing the prepreg of the present invention. In the case of using this method, one roll of the above specified long glass fiber base material (A) used for the prepreg of the present invention, and two rolls of long metal foil are prepared. The two metal foils are unrolled separately from the above two rolls, and the thermosetting resin composition (B) used for the prepreg of the present invention is applied on each metal foil to form an insulating resin layer for each metal foil. In the case of using the resin composition diluted by a solvent, after applying the thermosetting resin composition (B), thus obtained insulating resin layer is dried. Then, the insulating resin layer sides of two metal foils are disposed to face each other, and one or more glass fiber base materials (A) specified above are unrolled from the roll(s) in the space between the faced metal foils, followed by laminating and bonding the metal foils and the glass fiber base material(s) by means of a press roller. Next, the insulating resin layers are semi-cured by continuous hot press and cooled. Thus obtained long laminate is cut into a desired length. According to this method, lamination is continuously performed while conveying long base materials and metal foils on production lines, thereby, it is possible to obtain a long semi-cured laminate during the course of the production. The cut laminate in the semi-cured state is subjected to hot press by means of a press machine. Thus, the metal-clad laminate is obtained.

Next, the printed wiring board will be described.

The printed wiring board of the present invention comprises the laminate of the present invention subjected to wiring processing. The printed wiring board may be a multilayer printed wiring board.

The method of producing the multilayer printed wiring board is not particularly limited. For example, the method comprises the steps of: preparing a laminate having a metal foil on both sides; providing openings at desired positions by means of a drill; performing electroless plating on the openings and so on for conducting electricity between upper and lower surfaces of an inner layer circuit board; and etching the metal foils to form inner layer circuits.

Thus obtained inner layer circuit is preferably subjected to roughening treatment such as black oxide treatment. The openings may be appropriately filled with a conductive paste or a resin paste.

Next, an insulating resin layer is formed by laminating the prepreg of the present invention or an insulating resin sheet, comprising a thermoplastic resin film and an insulating resin layer formed on the thermoplastic resin film, so as to cover the inner layer circuit. The laminating method is not particularly limited, and a method using a vacuum press, a laminator under ordinary pressure or a laminator allowing hot press under vacuum for lamination is preferable. Among the above, the method using a laminator allowing hot press under vacuum is more preferable. Next, the insulating resin layer is cured by heating. The curing temperature is not particularly limited. For example, the insulating resin layer can be cured at a temperature in the range from 100 to 250° C., preferably from 150 to 200° C.

Next, openings are formed in the laminated insulating resin layer by irradiation of laser. It is preferable to remove resin residues, etc. after laser irradiation by an oxidant such as permanganate, bichromate or the like. Simultaneously, the smooth surface of the insulating resin layer can be roughened, thereby, it is possible to increase the adhesion of an outer layer circuit to be formed in the following metal plating.

Next, openings are provided in the insulating resin layer by means of a CO₂ laser. The outer layer circuit is formed on the surface of the insulating resin layer by electrolytic copper plating to conduct electricity between the outer layer circuit and an inner layer circuit. Electrode parts for connection are provided to the outer layer circuit for mounting semiconductor elements.

Then, a solder resist is formed on the outermost layer, the electrode parts for connection are exposed by exposure and development so as to mount the semiconductor elements, and the electrode parts for connection is subjected to nickel-gold plating processing. Thus, the multilayer printed wiring board is obtained by cutting into a desired size.

Next, the semiconductor device will be described.

The semiconductor device of the present invention comprises the printed wiring board of the present invention, and a semiconductor element mounted on the printed wiring board.

Semiconductor elements having solder bumps are mounted on the printed wiring board of the present invention. The printed wiring board and the semiconductor elements are connected via the solder bumps. Then, the space between the printed wiring board and the semiconductor element is filled with a liquid encapsulating resin. Thus, the semiconductor device is formed.

The solder bump is preferably constituted with an alloy of tin, lead, silver, copper, bismuth, etc. A method of connecting the semiconductor element and the printed wiring board may be as follows. After matching the positions of the electrode parts for connection on the printed wiring board and the solder bumps of the semiconductor elements, by means of a flip chip bonder, etc., solder bumps are heated to the temperature higher than the melting point by means of an IR reflow device, heated plate, or any other heating device, thereby, the printed wiring board and the solder bumps are fused to join. In order to improve connection reliability, a layer of metal having relatively low melting point such as solder paste, etc. may be preliminarily formed at the electrode part for connection on the printed wiring board. Before this bonding step, flux may be applied on the surface of the solder bumps and/or electrode part for connection on the printed wiring board. Thereby, the connection reliability improves.

### EXAMPLES

The present invention will be hereinafter explained further in detail with reference to Examples. The present invention may not be limited thereto. Herein, in Examples, “parts” represents “parts by weight” if not particularly mentioned. Also, the thickness of a layer and film represents an average film thickness.

A thermosetting resin composition used in Examples and Comparative examples is prepared using the following materials.

Epoxy resin A: biphenyl aralkyl modified phenol novolac type (2<n<3) (product name: NC3000; manufactured by Nippon Kayaku Co., Ltd.) represented by the following formula:

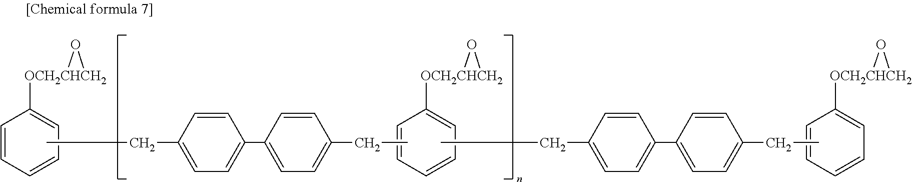

Epoxy resin B: naphthalenediol diglycidyl ether (product name: EPICLON HP-4032D; manufactured by DIC Corporation).

Epoxy resin C: cresol novolac type epoxy resin (product name: EPICLON N-665-EXP-S; manufactured by DIC Corporation).

Epoxy resin D: naphthalene-skeleton modified cresol novolac type epoxy resin (product name: EXA-7320; manufactured by DIC Corporation).

Cyanate resin A: novolac type cyanate resin (product name: PRIMASET PT-30; manufactured by LONZA Japan) represented by the following formula:

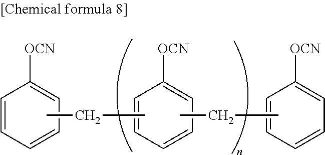

Cyanate resin B: p-xylene modified naphthol aralkyl type cyanate represented by the following formula (reactant of naphtholaralkyl type phenol resin (product name: SN-485; manufactured by Nippon Steel Chemical Co., Ltd.) and cyanogen chloride):

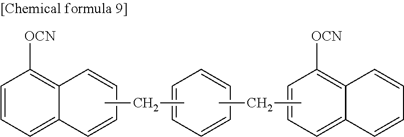

Phenol resin A: biphenyl aralkyl modified phenol novolac resin (n=about 2) (product name: MEH-7851-S; manufactured by MEIWA PLASTIC INDUSTRIES, LTD.) represented by the following formula:

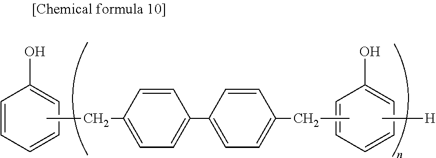

Phenol resin B: phenol novolac resin (product name: PR-51470; manufactured by Sumitomo Bakelite Co., Ltd.).

Maleimide resin: bis(3-methyl-5-ethyl-4-maleimidophenyl)methane (product name: BMI-70; manufactured by K.I Chemical Industry Co., Ltd.).

Inorganic filler A: fused silica (product name: SO-25R; manufactured by ADMATECHS Co., Ltd.; average particle diameter: 0.5 μm).

Inorganic filler B: fused silica (product name: SO-32R; manufactured by ADMATECHS Co., Ltd.; average particle diameter: 1 μm).

Inorganic filler C: silicone composite powder (product name: KMP-600; manufactured by Shin-Etsu Chemical Co., Ltd.; average particle diameter: 5 μm).

Inorganic filler D: aluminum hydroxide (product name: BE-033; manufactured by Nippon Light Metal Company, Ltd.; average particle diameter: 2 μm).

Inorganic filler E: talc (product name: LMS-200; manufactured by Fuji Talc Industrial Co., Ltd.; average particle diameter: 5 μm).

Inorganic filler F: boehmite (product name: BMT-3L; manufactured by KAWAI LIME INDUSTRY CO., LTD.; average particle diameter: 3 μm).

Curing catalyst A: phosphorous catalyst of the compound corresponding to the above formula (3) (product name: C05-MB; manufactured by Sumitomo Bakelite Co., Ltd.).

Curing catalyst B: zinc octylate.

Curing catalyst C: dicyandiamide.

Coupling agent: epoxy silane.

### Production Example 1

### Preparation of Resin Varnish of Thermosetting Resin Composition (B)

11.2 parts by weight of epoxy resin A, 20.0 parts by weight of cyanate resin A, 8.8 parts by weight of phenol resin A, and 0.3 parts by weight of the coupling agent were dissolved and dispersed in methyl ethyl ketone. Further, 59.7 parts by weight of inorganic filler A was added therein followed by agitating for 10 minutes by means of a high speed agitator. Thus, a resin varnish having a solid content of 70% by weight was prepared.

### Production Examples 2 to 9

### Preparation of Resin Varnish of Thermosetting Resin Composition (B)

Resin varnish of Production examples 2 to 9 was prepared similarly as in Production example 1 except that the composition of Production example 1 was changed to the compositions of Production examples 2 to 9 as shown in Table 1.

TABLE 1

| | | Production | Production | Production | Production | Production | Production | Production | Production | Production |
|---|---|---|---|---|---|---|---|---|---|---|
| | | example 1 | example 2 | example 3 | example 4 | example 5 | example 6 | example 7 | example 8 | example 9 |
| Epoxy resin A | NC3000 | 11.2 | 9.8 | 8.4 | 9.8 | 8.4 | 16.6 | | 15.4 | |
| Epoxy resin B | HP4032D | | | | | | | | 1.9 | |
| Epoxy resin C | N665EXPS | | | | | | | | | 17.8 |
| Epoxy resin D | EXA7320 | | | | | | | 14.9 | | |
| Cyanate resin A | PT30 | 20.0 | 17.5 | 15.0 | 17.5 | 15.0 | 14.0 | 14.9 | | |
| Cyanate resin B | SN485 derivative | | | | | | | | 12.7 | |
| Phenol resin A | MEH7851 | 8.8 | 7.7 | 6.6 | 7.7 | 6.6 | 4.4 | | | |
| Phenol resin B | PR51470 | | | | | | | | | 11.9 |
| Maleimide resin | BMI70 | | | | | | | | 8.5 | |
| Inorganic filler A | SO25R | 59.7 | 64.7 | 69.7 | | | | 69.7 | 51.7 | 39.8 |
| Inorganic filler B | SO32R | | | | 44.8 | 47.3 | 34.8 | | | |
| Inorganic filler C | KMP600 | | | | | | | | 9.0 | |
| Inorganic filler D | BE033 | | | | 19.9 | 22.4 | | | | 19.9 |
| Inorganic filler E | LMS200 | | | | | | | | | 10.0 |
| Inorganic filler F | BMT-3L | | | | | | 29.9 | | | |
| Curing catalyst A | Phosphorous catalyst | | | | | | | 0.3 | | |
| Curing catalyst B | Zinc octylate | | | | | | | | 0.4 | |
| Curing catalyst C | Dicyandiamide | | | | | | | | | 0.3 |
| Coupling agent | Epoxy silane | 0.3 | 0.3 | 0.4 | 0.3 | 0.4 | 0.3 | 0.4 | 0.3 | 0.4 |

### Example 1

### (1) Production of Prepreg

The resin varnish of the thermosetting resin composition obtained in Production example 1 was impregnated into a glass fiber base material (product name: WEA2117A; manufactured by Nitto Boseki Co., Ltd.; thickness: 96 μm; mass: 115 g/m²; E glass), in which inorganic particles having an average particle diameter of 100 nm were attached on the glass fiber surface. The glass fiber base material was dried in a heating oven at 150° C. for 2 minutes. Thus, a prepreg having the resin composition in an amount of 45.2% by weight based on solid content was obtained.

The glass fiber base material, in which the inorganic particles having an average particle diameter of 100 nm were attached on the glass fiber surface, was prepared by dipping a glass fiber substrate in a solution containing colloidal silica having an average particle diameter of 100 nm, and applying ultrasonic vibration.

### (2) Production of Copper-Clad Laminate

The prepreg was sandwiched between two copper foils having a thickness of 18 μm, and subjected to hot press molding at 200° C. under the pressure of 4 MPa for 2 hours. Thus, a laminate having copper foils each having a thickness of 0.1 mm on both surfaces was obtained.

### (3) Production of Multilayer Printed Wiring Board

After performing through hole processing on the above obtained copper-clad laminate using a drill bit having a diameter of 0.1 mm, through holes were filled by plating. Further, a circuit was formed on both surfaces by etching and used as an inner layer circuit board.

Separately, the resin varnish of Production example 1 was applied on a PET film (product name: SFB38; manufactured by Mitsubishi Plastics, Inc.; thickness: 38 μm) by means of a comma coater so as to form an epoxy resin layer having a thickness of 40 μm after drying. Then, the PET film was dried at 150° C. for 5 minutes by means of a drying machine. Thus, a resin sheet was produced.

The epoxy resin layer of the resin sheet obtained above was layered on the inner layer circuit board, and then subjected to vacuum hot press molding at 100° C. under the pressure of 1 MPa by means of a vacuum pressurized laminator. After peeling the PET film of the base material from the resin sheet, heat-curing was carried out at 170° C. for 60 minutes by means of a hot air drying machine. Thus, a multilayer printed wiring board was obtained.

### Examples 2 and 3

A prepreg each for Examples 2 and 3 having the resin composition in an amount of 45.2% by weight based on solid component was produced similarly as in Example 1 except that the resin varnish obtained in Production example 2 or Production example 4 was respectively used instead of the resin varnish obtained in Production example 1. Further, a copper-clad laminate was produced using thus obtained prepreg similarly as in Example 1. Furthermore, a multilayer printed wiring board was produced using thus obtained copper-clad laminate similarly as in Example 1.

### Examples 4 to 10

A prepreg each for Examples 4 to 10 having the resin composition in an amount of 49.6% by weight based on solid content was produced similarly as in Example 1 except that the glass fiber base material was changed to a glass fiber base material (product name: WEA116E; manufactured by Nitto Boseki Co., Ltd.; thickness: 90 μm; mass: 106 g/m²; E glass), in which inorganic particles having an average particle diameter of 100 nm were attached on the glass fiber surface, and the resin varnish each of the above Production examples 3 to 9 as shown in Table 2 was used. Further, a copper-clad laminate was produced using thus obtained prepreg similarly as in Example 1. Furthermore, a multilayer printed wiring board was produced using thus obtained copper-clad laminate similarly as in Example 1. A SEM photograph of the surface of the above used glass fiber base material in which inorganic particles having an average particle diameter of 100 nm were attached is shown in FIG. 1.

In Example 7, the drill durability upon through hole processing by means of the drill bit was excellent.

### Example 11

A prepreg having the resin composition in an amount of 49.6% by weight based on solid content was produced similarly as in Example 1 except that the glass fiber base material was changed to a glass fiber base material (product name: WTX116E; manufactured by Nitto Boseki Co., Ltd.; thickness: 90 μm; mass: 106 g/m²; T glass), in which inorganic particles having an average particle diameter of 100 nm were attached on the glass fiber surface, and the resin varnish of the above Production example 3 as shown in Table 2 was used. Further, a copper-clad laminate was produced using thus obtained prepreg similarly as in Example 1. Furthermore, a multilayer printed wiring board was produced using thus obtained copper-clad laminate similarly as in Example 1.

### Comparative Example 1

A prepreg having the resin composition in an amount of 45.2% by weight based on solid content was produced similarly as in Example 1 except that the glass fiber base material was changed to a glass fiber base material (product name: WEA2117A; manufactured by Nitto Boseki Co., Ltd.; thickness: 96μm; mass: 115 g/m²), in which inorganic particles were not attached on the glass fiber surface. Further, a copper-clad laminate was produced using thus obtained prepreg similarly as in Example 1. Furthermore, a multilayer printed wiring board was produced using thus obtained copper-clad laminate similarly as in Example 1.

### Comparative Examples 2 and 3

A prepreg each for Comparative examples 2 and 3 having the resin composition in an amount of 45.2% by weight based on solid content was produced similarly as in Comparative example 1 except that the resin varnish obtained in Production example 2 or Production example 4 was respectively used instead of the resin varnish obtained in Production example 1. Further, a copper-clad laminate was produced using thus obtained prepreg similarly as in Example 1. Furthermore, a multilayer printed wiring board was produced using thus obtained copper-clad laminate similarly as in Example 1.

### Comparative Examples 4 to 10

A prepreg each for Comparative examples 4 to 10 having the resin composition in an amount of 49.6% by weight based on solid content was produced similarly as in Comparative example 1 except that the glass fiber base material was changed to a glass fiber base material (product name: WEA116E; manufactured by Nitto Boseki Co., Ltd.; thickness: 90 μm; mass: 106 g/m²), in which inorganic particles were not attached on the glass fiber surface, and the resin varnish each of the above Production examples 3 to 9 as shown in Table 2 was used. Further, a copper-clad laminate was produced using thus obtained prepreg similarly as in Example 1. Furthermore, a multilayer printed wiring board was produced using thus obtained copper-clad laminate similarly as in Example 1. A SEM photograph of the surface of the above used glass fiber base material, in which inorganic particles were not attached on the glass fiber surface, is shown in FIG. 2.

### Comparative Example 11

A prepreg having the resin composition in an amount of 49.6% by weight based on solid content was produced similarly as in Example 1 except that the glass fiber base material was changed to a glass fiber base material (product name: WTX116E; manufactured by Nitto Boseki Co., Ltd.; thickness: 90μm; mass: 106 g/m²), in which inorganic particles were not attached on the glass fiber surface, and the resin varnish of the above Production example 3 as shown in Table 2 was used. Further, a copper-clad laminate was produced using thus obtained prepreg similarly as in Example 1. Furthermore, a multilayer printed wiring board was produced using thus obtained copper-clad laminate similarly as in Example 1.

### [Evaluation]

### 1. Impregnation

The copper-clad laminates obtained in Examples and Comparative examples were cross-sectionally observed. A scanning electron microscope (manufactured by KEYENCE Corporation.) was used for the cross-sectional observation.

The impregnation was evaluated as follows from the area of voids which was cross-sectionally observed:

∘: the area of voids cross-sectionally observed is less than 10% of the total area;

Δ: the area of voids cross-sectionally observed is 10 to 30% of the total area; and

×: the area of voids cross-sectionally observed exceeds 30% of the total area.

The evaluation results are shown in Table 2.

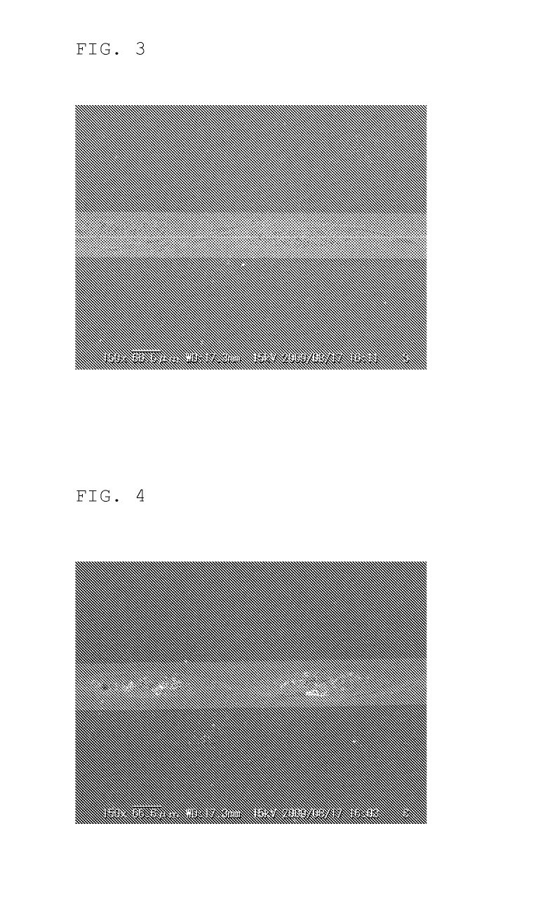

Further, a SEM photograph of the cross-sectional observation of the copper-clad laminate of Example 4 is shown in FIG. 3. A SEM photograph of the cross-sectional observation of the copper-clad laminate of Comparative example 4 is shown in FIG. 4.

### 2. Thermal Expansion Coefficient

The copper foil of the copper-clad laminate each obtained in Examples and Comparative examples was overall etched, and a test piece of 4 mm×20 mm was cut out from thus obtained laminate. The linear expansion coefficient (average linear expansion coefficient) in a surface direction was measured at temperatures from 50 to 150° C. under the condition of 10° C./minute by means of TMA (Thermomechanical Analyzer; product name: Q400; manufactured by TA Instruments). In Table 2, “NA” refers to the case that obvious voids were visually observed in the test piece, and the linear expansion coefficient of the test piece was not measured, since it is unworthy of measuring the linear expansion coefficient.

### 3. Solder Heat Resistance

A 50-mm-square sample was cut out from the copper-clad laminate each obtained in Examples and Comparative examples. The ¾ area (the whole area of one surface, and the half area of the other surface) of the copper foils on both surfaces was etched. After the sample was processed by means of a pressure cooker at 121° C. for two hours, the sample was dipped in solder at 260° C. for 30 seconds. Then, presence of swelling was observed. The symbols refer to the following:

∘: no swelling was observed; and

×: swelling was observed.

### 4. Insulation Reliability Test

An insulation reliability test between walls of through holes was carried out using the multilayer printed wiring board each obtained in Examples and Comparative examples. The voltage of 20 V was applied to a sample in a pattern of 150 μm between walls in an environment of 130° C./85% for 200 hours, and then the sample was removed from a test chamber. Thus, the resistance value under normal temperature and normal humid environment was measured. The symbols refer to the following:

∘: resistance value is 10⁸Ω or more; and

×: resistance value is less than 10⁸Ω.

TABLE 2

| | | Amount of | | | Thermal linear | | |
|---|---|---|---|---|---|---|---|
| | | filler in | | | expansion | | |
| | | composition | | | coefficient | Solder heat | Insulation |
| | Resin varnish | (weight %) | Glass fiber base material | Impregnation | (ppm) | resistance | reliability |
| Example 1 | Production Example 1 | 60 | WEA2117A + particle | ∘ | 10 | ∘ | ∘ |
| Example 2 | Production Example 2 | 65 | WEA2117A + particle | ∘ | 8 | ∘ | ∘ |
| Example 3 | Production Example 4 | 65 | WEA2117A + particle | ∘ | 8 | ∘ | ∘ |
| Example 4 | Production Example 3 | 70 | WEA116E + particle | ∘ | 8 | ∘ | ∘ |
| Example 5 | Production Example 4 | 65 | WEA116E + particle | ∘ | 10 | ∘ | ∘ |
| Example 6 | Production Example 5 | 70 | WEA116E + particle | ∘ | 8 | ∘ | ∘ |
| Example 7 | Production Example 6 | 65 | WEA116E + particle | ∘ | 10 | ∘ | ∘ |
| Example 8 | Production Example 7 | 70 | WEA116E + particle | ∘ | 8 | ∘ | ∘ |
| Example 9 | Production Example 8 | 61 | WEA116E + particle | ∘ | 9 | ∘ | ∘ |
| Example 10 | Production Example 9 | 70 | WEA116E + particle | ∘ | 9 | ∘ | ∘ |
| Example 11 | Production Example 3 | 70 | WTX116E + particle | ∘ | 6 | ∘ | ∘ |
| Comparative example 1 | Production Example 1 | 60 | WEA2117A | Δ | NA | x | x |
| Comparative example 2 | Production Example 2 | 65 | WEA2117A | x | NA | x | x |
| Comparative example 3 | Production Example 4 | 65 | WEA2117A | x | NA | x | x |
| Comparative example 4 | Production Example 3 | 70 | WEA116E | x | NA | x | x |
| Comparative example 5 | Production Example 4 | 65 | WEA116E | Δ | NA | x | x |
| Comparative example 6 | Production Example 5 | 70 | WEA116E | x | NA | x | x |
| Comparative example 7 | Production Example 6 | 65 | WEA116E | Δ | NA | x | x |
| Comparative example 8 | Production Example 7 | 70 | WEA116E | x | NA | x | x |
| Comparative example 9 | Production Example 8 | 61 | WEA116E | x | NA | x | x |
| Comparative example 10 | Production Example 9 | 70 | WEA116E | x | NA | x | x |
| Comparative example 11 | Production Example 3 | 70 | WTX116E | x | NA | x | x |

It is clear from Examples of the present invention that even if the glass fiber base material having high density capable of achieving low linear expansion characteristics and high rigidity is used and the amount of the filler in the thermosetting resin composition is increased, it is possible to increase impregnation of the resin composition into the glass fiber base material, and significantly decrease generation of voids in the glass fiber base material, by using the glass fiber material, in which the inorganic particles having an average particle diameter of 500 nm or less are attached on the glass fiber surface, thereby, it is possible to obtain a laminate capable of achieving low linear expansion characteristics, high rigidity, and high heat resistance, therefore, it is possible to increase the reliability of the semiconductor device.

To the contrary, it is clear from Comparative examples using the glass fiber base material, in which the inorganic particles are not attached on the glass fiber surface, that if the glass fiber base material having high density capable of achieving low linear expansion and high rigidity is used and the amount of the filler in the thermosetting resin composition is increased, voids (spaces) that the resins and the fillers are not impregnated generate in the glass fiber base material, therefore, the solder heat resistance deteriorates and the reliability of the semiconductor device decreases.

1. A prepreg comprising a glass fiber base material (A) impregnated with a thermosetting resin composition (B), wherein an inorganic particle having an average particle diameter of 500 nm or less is attached on a glass fiber surface of the glass fiber base material (A).

2. The prepreg according to claim 1, wherein the inorganic particle of the glass fiber base material (A) is a silica particle.

3. The prepreg according to claim 1, wherein a thickness of the glass fiber base material (A) is 150 μm or less.

4. The prepreg according to claim 1, wherein the glass fiber surface of the glass fiber base material (A) is processed by a treatment liquid in which the inorganic particles are dispersed.

5. The prepreg according to claim 1, wherein the thermosetting resin composition (B) contains an inorganic filler.

6. The prepreg according to claim 1, wherein the thermosetting resin composition (B) contains an epoxy resin.

7. The prepreg according to claim 1, wherein the thermosetting resin composition (B) contains a cyanate resin.

8. The prepreg according to claim 1, wherein the inorganic filler contained in the thermosetting resin composition (B) has an average particle diameter of from 0.1 μm to 5.0 μm.

9. A laminate comprising the prepregs defined by claim 1 being cured.

10. The laminate according to claim 9 comprising a conducting layer disposed on at least one outer surface of the prepreg.

11. A printed wiring board comprising the laminate defined by claim 9 subjected to wiring processing.

12. A semiconductor device comprising the printed wiring board defined by claim 11, and a semiconductor element mounted on the printed wiring board.
